(19) United States
(12) Patent Application Publication
(10) Pub. No.: US 2025/0132173 A1
(43) Pub. Date: Apr. 24, 2025

(54) SUBSTRATE CLEANING APPARATUS

(71) Applicant: SAMSUNG ELECTRONICS CO., LTD., Suwon-si (KR)

(72) Inventors: Heegeun Kim, Suwon-si (KR); Donghoon Kwon, Suwon-si (KR)

(21) Appl. No.: 18/736,256

(22) Filed: Jun. 6, 2024

(30) Foreign Application Priority Data
Oct. 18, 2023 (KR) 10-2023-0139276

(51) Int. Cl. H01L 21/67

(52) U.S. Cl. CPC H01L 21/67046

(57) ABSTRACT

An example substrate cleaning apparatus includes a roll brush that cleans a surface of a substrate. The roll brush includes a drive shaft with a predetermined length and a plurality of brush members positioned around an outside circumference of the drive shaft. One of the plurality of the brush members is provided with a rotation speed lower than the others.

### CROSS-REFERENCE TO RELATED APPLICATION

This application claims priority to and the benefit of Korean Patent Application No. 10-2023-0139276 filed in the Korean Intellectual Property Office on Oct. 18, 2023, the entire contents of which are incorporated herein by reference.

### BACKGROUND

In order to form fine structures (e.g., metal layer, barrier layer, insulation layer, etc.) on a substrate (e.g., semiconductor wafer), a planarization process of polishing the surface of the substrate may be performed using a substrate cleaning apparatus. The planarization process may be performed through a CMP process or the like. Particles (e.g., slurry residue, polishing crumbs, etc.) may exist on the substrate where the planarization process is performed. Accordingly, additional cleaning process may be performed after the planarization process in order to remove such particles from the substrate.

### SUMMARY

The present disclosure relates to a substrate cleaning apparatus capable of cleaning the substrate effectively.

In some implementations, a substrate cleaning apparatus comprises a roll brush module cleaning a surface of a substrate. The roll brush module includes a drive shaft having a predetermined length; and a plurality of brush members disposed around an outside circumference of the drive shaft. One of the plurality of brush members is provided with a rotation speed lower than the others.

In some implementations, a substrate cleaning apparatus comprises a substrate support member rotatably supporting a substrate and a roll brush module cleaning a surface of the substrate. The roll brush module may comprise a drive shaft having a predetermined length, a center brush member positioned to pass through a center of the substrate, and a side brush members disposed on each side of the center brush member. The center brush member is provided with a rotation speed lower than the side brush member.

In some implementations, a substrate cleaning apparatus comprises a substrate support member rotatably supporting a substrate and a roll brush module cleaning a surface of the substrate. The roll brush module may comprise a drive shaft having a predetermined length, a center brush member positioned to pass through a center of the substrate, and a side brush members disposed on each side of the center brush member. The center brush member and the side brush member are provided to be rotatable with respect to the drive shaft, and the center brush member is provided with a rotation speed lower than the side brush member.

### BRIEF DESCRIPTION OF THE DRAWINGS

FIG. 1 is a drawing representing an example of a substrate cleaning apparatus.

FIG. 2 is an example top plan view representing a roll brush module and an auxiliary brush module of the substrate cleaning apparatus of FIG. 1.

FIG. 3 is an example cross-sectional view of a center brush member according to the direction intersecting the length direction of the drive shaft.

FIG. 4 is an example cross-sectional view of a side brush member according to the direction the direction intersecting the length direction of the drive shaft.

FIG. 5 is a drawing representing an example of a speed control member and an example of a connection member.

FIG. 6 is a drawing representing an example of a speed control member.

FIG. 7 is a drawing representing an example of a speed control member.

FIG. 8 is a drawing representing an example of a roll brush module and an example of an auxiliary brush module.

FIG. 9 is a drawing representing an example of a roll brush module and an example of an auxiliary brush module.

FIG. 10 is a drawing representing an example of a roll brush module.

### DETAILED DESCRIPTION

Hereinafter, with reference to the accompanying drawing, several implementations of the present disclosure will be described in detail so that a person of an ordinary skill can easily practice it in the technical field to which the present disclosure belongs. The present disclosure may be implemented in several different forms and is not limited to the implementations described herein.

Throughout the specification, identical or similar component is assigned the same reference numerals.

In addition, the size and thickness of each component shown in the drawing may be scaled for convenience of explanation. In the drawings, the thickness of layers, films, panels, regions, etc., may be enlarged for clarity or better understanding and ease of description.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present.

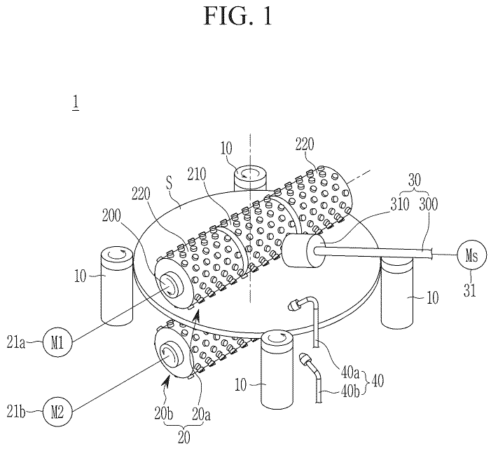

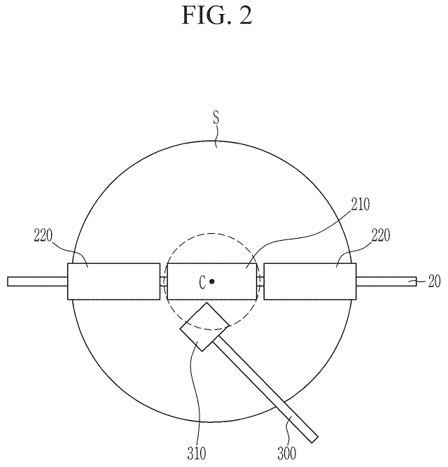

FIG. 1 is a drawing representing an example of a substrate cleaning apparatus 1. FIG. 2 is an example top plan view representing a roll brush module 20 and an auxiliary brush module 30 of the substrate cleaning apparatus 1 of FIG. 1.

Referring to FIG. 1 and FIG. 2, the substrate cleaning apparatus 1 includes a substrate support member 10, a roll brush module 20, an auxiliary brush module 30 and a nozzle 40.

The substrate cleaning apparatus 1 may perform a cleaning process on the substrate S. For example, the substrate cleaning apparatus 1 may perform cleaning on the foreign substances such as particle placed in the substrate S after a chemical mechanical polishing (CMP) process.

The substrate support member 10 may support the substrate S. In addition, the substrate support member may rotate the substrate S along an axis of a normal line passing through the center C of the substrate S. The plurality of substrate support members 10 may be disposed on a circumference which is correspond to the exterior side of the substrate S. Each of the plurality of substrate support members 10 may be rotated along an axis of the direction which is parallel to the normal line of substrate S. That is, the substrate support member 10 may be understood as a roller structure. When the plurality of substrate support members 10 rotate in the same direction while being in contact with the exterior side of the substrate S, the substrate S may be rotated in a supported state on the substrate support member 10. A groove for supporting the exterior side of the substrate S may be disposed around the outside circumference of the substrate support member 10.

The roll brush module 20 may be rotated while being in contact with the outer surface of the substrate S to enable cleaning a surface of the substrate S. The roll brush module 20 may include a first roll brush module 20a and a second roll brush module 20b.

The first roll brush module 20a may be disposed on a first surface of the substrate S. The first roll brush module 20a may be moved in an upward and downward direction in order to contact with the substrate S. In addition, the first roll brush module 20a may move in the radius direction of the substrate S to enable a sweep motion with respect to the substrate S. The first roll brush module 20a may rotate while being in contact with the first surface of the substrate S to enable cleaning on the first surface of the substrate S. The second roll brush module 20b may be disposed on a second surface of the substrate S. the second roll brush module 20b may be moved in an upward and downward direction to contact the substrate S. In addition, the second roll brush module 20b may move in the radius direction of the substrate S to enable a sweep motion with respect to the substrate S. The second roll brush module 20b may rotate while being in contact with the second surface of the substrate S to enable cleaning on the second surface of the substrate S. In FIG. 1, the first surface of the substrate S faces upward and becomes an upper surface, while the second surface of the substrate S faces downward and becomes a lower surface.

The first roll brush module 20a may include a drive shaft 200, a plurality of brush members 210 and 220. The first roll brush module 20a is connected to the first driving member 21a and rotated by power provided by the first driving member 21a. The first driving member 21a may be provided as a motor or the like.

The drive shaft 200 has a predetermined length. When viewed along an upward and downward direction, the drive shaft 200 may be disposed to pass through the center C of the substrate S. A length of the drive shaft 200 may be provided to be larger than a diameter of the substrate S and each end of the drive shaft 200 having both ends may be positioned on an outside of the edge of the substrate S. The first driving member 21a may be connected to the drive shaft 200.

The plurality of brush members 210 and 220 may be disposed around the outside circumference of the drive shaft 200, respectively. The plurality of brush members 210, 220 may be rotated according to the rotation of the drive shaft 200, respectively. The plurality of brush members 210 and 220 may be provided in a cylinder shape, respectively. Protrusions may be disposed for improving cleaning efficiency around the outside circumference of the brush members 210 and 220,

One of the plurality of brush members 210, 220 may be provided with a rotation speed lower than the others. At least one of the plurality of brush members 210 and 220 may be rotated at a rotation speed that is lower than the rotation speed of the drive shaft 200. That is, at least one of the plurality of brush members 210 and 220 may be provided to be rotatable with respect to the drive shaft 200, so that when the drive shaft 200 rotates 360° (ie, one revolution), it may rotate less than 360° (ie, one revolution).

The brush members 210 and 220 may include a center brush member 210 and a side brush member 220.

The center brush member 210 may be disposed around the outside circumference of the drive shaft 200. The center brush member 210 may be provided in a cylinder shape. Protrusions may be disposed for improving cleaning efficiency around the outside circumference of the center brush member 210,

When viewed along an upward and downward direction, the center brush member 210 may be positioned to pass through the center C of the substrate S. The center brush member 210 may be positioned in a manner where the lengths extending in both directions correspond to each other with respect to the center C of the substrate S as a reference. That is, both ends of the center brush member 210 may be positioned on a circumference having a predetermined radius with respect to the center C of the substrate S as a reference.

In this case, if the circle of the predetermined radius intersects one point at both ends of the center brush member 210, respectively, it may be understood that both ends of the center brush member 210 may be positioned along the circumference. In addition, if both ends of the center brush member 210 are inscribed to a circle of a predetermined radius, respectively, it may be understood that both ends of the center brush member 210 are positioned along the circumference.

The side brush member 220 may be disposed around the outside circumference of the drive shaft 200. The side brush member 220 may be provided in a cylinder shape. In a vertical direction to the drive shaft 200, the size of the outside circumference of the side brush member 220 may correspond to the size of the outside circumference of the center brush member 210. Protrusions may be disposed for improving cleaning efficiency around the outside circumference of the side brush member 220,

The side brush member 220 may be disposed on each side of the center brush member 210 having both sides. The inner end of the side brush member 220 faces the center C of the substrate S, and the outer end of the side brush member 220 faces the opposite side of the center C of the substrate S.

An inner end of the side brush member 220 may be disposed to be spaced apart from one end of the center brush member 210. An outer end of the side brush member 220 may be positioned on an outside of the edge of the substrate S. When viewed along an upward and downward direction, the side brush member 220 may be positioned on a region of between a predetermined distance separated point from the center C of the substrate S and an edge of the substrate S. That is, the side brush member 220 may be positioned on the outside of a circle having a predetermined radius with respect to the center C of the substrate S as a reference. In this case, one point of the inner end of the side brush member 220 may be circumscribed to the circle of the predetermined radius. In addition, the inner end of the side brush member 220 may be positioned to be spaced apart from the circle having a predetermined radius.

Side brush members 220 disposed on each side of the center brush member 210 having both sides may have a corresponding length along the length direction of the drive shaft 200.

The second roll brush module 20b may be connected to the second driving member 21b and may be rotated by power provided by the second driving member 21b. The second roll brush module 20b may be rotated in an opposite direction to the first roll brush module 20a. The second driving member 21b may be provided as a motor or the like. The second roll brush module 20b may have a structure corresponding to the first roll brush module 20a. Accordingly, a description of the second roll brush module 20b with respect to overlapping aspects with the first roll brush module 20a will not be repeated.

The auxiliary brush module 30 may be positioned on a different region from the roll brush module 20 and may clean a surface of the substrate S. Specifically, the roll brush module 20 may have a gap in a region where one ends of the plurality of brush members 210 and 220 face each other. In the area where the gap between such brush members 210 and 220 is positioned, cleaning of the substrate S by the roll brush module 20 may be insufficient. Accordingly, the auxiliary brush module 30 may clean the substrate S by positioning one ends of the plurality of brush members 210 and 220 on the gap between regions facing each other on the substrate S.

The auxiliary brush module 30 may be connected to the auxiliary driving member 31 and may be rotated by the power provided by the auxiliary driving member 31. The auxiliary driving member 31 may be provided as a motor or the like.

The auxiliary brush module 30 may be positioned on the first surface of the substrate S corresponding to the first roll brush module 20a. Accordingly, the auxiliary brush module 30 may perform cleaning on the first surface of the substrate S. In addition, the auxiliary brush module 30 may be positioned on a second surface of the substrate S corresponding to the second roll brush module 20b. Accordingly, the auxiliary brush module 30 may perform cleaning on the second surface of the substrate S. FIG. 1 illustrates a case where an auxiliary brush module 30 is positioned on a first surface of a substrate S.

The auxiliary brush module 30 may include an auxiliary drive shaft 300 and an auxiliary brush member 310.

The auxiliary drive shaft 300 may have a predetermined length. When viewed along an upward and downward direction, the auxiliary drive shaft 300 may be positioned to be inclined with respect to the radius direction with respect to the center C of the substrate S. Also, when viewed along an upward and downward direction, the auxiliary drive shaft 300 may be positioned along the radius direction with respect to the center C of the substrate S. The auxiliary drive shaft 300 may be positioned to be spaced apart from the roll brush module 20. Accordingly, it may be possible to prevent interference or collision between the roll brush module 20 and the auxiliary brush module 30. The auxiliary drive shaft 300 may be connected to the auxiliary driving member 31.

The auxiliary brush member 310 may be disposed around the outside circumference of the auxiliary drive shaft 300. The auxiliary brush member 310 may be provided in a cylinder shape. Protrusions may be disposed for improving cleaning efficiency around the outside circumference of the auxiliary brush member 220. The auxiliary brush member 310 may be positioned to be spaced apart from the center C of the substrate S in the radius direction. When viewed along an upward and downward direction, the auxiliary brush member 310 may be positioned on a circumference passing through a gap formed in a region where one ends of the plurality of brush members 210 and 220 face each other. That is, a circle passing through one end of the center brush member 210 may pass through the auxiliary brush member 310. In addition, a circle passing through an inner end of the side brush member 220 may pass through an auxiliary brush member 310. As the substrate S rotates, a region positioned on the gap formed between one end of the plurality of brush members 210 and 220 in the substrate S may pass through the auxiliary brush member 310. Accordingly, the auxiliary brush member 310 may perform cleaning for the region positioned in the gap formed between one end of the plurality of brush members 210 and 220 in the substrate S.

The nozzle 40 may spray chemical on the substrate S. Chemical sprayed on the substrate S may improve cleaning efficiency. The chemical sprayed on the substrate S may be a cleaning solution. The nozzle 40 may include a first nozzle 40a and a second nozzle 40b. The first nozzle 40a may spray chemical onto the first surface of the substrate S. The second nozzle 40b may spray chemical onto the second surface of the substrate S.

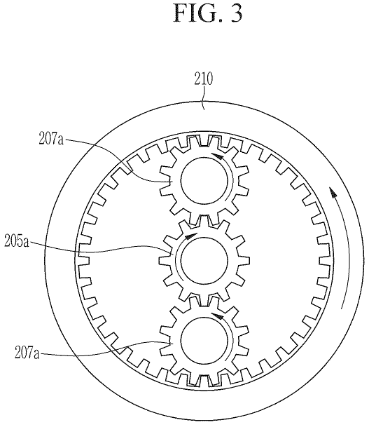

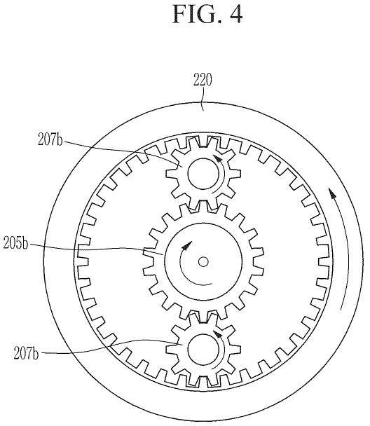

FIG. 3 is an example cross-sectional view of the center brush member 210 according to the direction intersecting the length direction of the drive shaft 200. FIG. 4 is an example cross-sectional view of the side brush member 220 according to the direction intersecting the length direction of the drive shaft 200.

Referring to FIG. 3 and FIG. 4, the brush members 210 and 220 may be provided to have an empty space inside at least in some sections. The brush members 210 and 220 may be rotated with respect to the drive shaft 200. The speed control members 205a and 205b may be disposed around the outside circumference of the drive shaft 200. The inner center region of the speed control members 205a and 205b may be connected to the drive shaft 200. The speed control members 205a and 205b may be disposed in a space formed inside of the brush members 210 and 220. The speed control members 205a and 205b may be coupled to the drive shaft 200, so that they may be rotated together with the drive shaft 200. Accordingly, the speed control members 205a and 205b may be rotated at the same speed as the drive shaft 200. For example, the speed control members 205a and 205b may be coupled to the outside circumference of the drive shaft 200. The speed control member 205a, 205b may be disposed between the drive shaft 200 and the inner side of the brush members 210 and 220, so that the brush members 210, 220 with respect to the rotation speed of the drive shaft 200 may be decelerated and rotated. For example, a connection members 207a, 207b may be disposed between the speed control members 205a, 205b and the inner side of the brush members 210, 220. The speed control members 205a and 205b may be provided to be in contact with the connection members 207a and 207b. In addition, the connection members 207a and 207b may be provided to be in contact with the inner side of the brush members 210 and 220. Accordingly, when the speed control members 205a and 205b may be rotated, the connection members 207a and 207b and the brush members 210 and 220 may be rotated. At this point, the rotation speed of the brush members 210 and 220 may be decelerated compared to the rotation speed of the speed control members 205a and 205b.

For example, the speed control members 205a and 205b may be provided to have a gear structure. In addition, in the inner side of brush members 210 and 220, a gear tooth may be disposed along the circumference direction intersecting the length direction of the drive shaft 200. In addition, the connection members 207a and 207b with a gear structure may be disposed between the speed control members 205a, 205b and the inner side of the brush members 210, 220. A plurality of connection members 207a and 207b may be provided and each of the connection members 207a and 207b may have a structure corresponding to each other. Accordingly, if the drive shaft 200 is rotated, the rotation speed of the brush members 210 and 220 may be decelerated compared to the rotation speed of the drive shaft 200 in proportion to the ratio of the number of gear tooth of the speed control members 205a and 205b and the number of gear tooth disposed on the inner side of the brush members 210 and 220. For example, if the number of gear tooth placed in the inner side of brush members 210 and 220 is double compared to the number of gear tooth of speed control members 205a and 205b, the rotation speed of brush members 210 and 220 may be a half compared to the rotation speed of drive shaft 200.

The speed control members 205a and 205b and the connection members 207a and 207b may be disposed inside of the plurality of brush members 210 and 220, respectively. At this time, the gear tooth ratio of the center brush member 210 and the gear tooth ratio of the center speed control member 205a disposed inside of the center brush member 210 may be provided differently from the gear tooth ratio of the side brush member 220 and the gear tooth ratio of the side speed control member 205b disposed inside of the side brush member 220. The gear tooth of the center brush member 210/the gear tooth of the center speed control member 205a may be provided larger than the gear tooth of side brush member 220/the gear tooth of the side speed control member 205b. The center connection member 207a disposed around the outside circumference of the center speed control member 205a may be larger than the side connection member 207b disposed around the outside circumference of the side speed control member 205b. Accordingly, the center brush member 210 has a greater deceleration than the side brush member 220 so that the rotation speed of the center brush member 210 may be lower than the rotation speed of the side brush member 220.

In the substrate cleaning apparatus 1, the roll brush module 20 may provide one of the plurality of brush members 210, 220 with a rotation speed lower than the others. That is, the roll brush module 20 is provided with a rotation speed of the center brush member 210 that may clean the central region C of the substrate S lower than the side brush member 220 that may clean the side region of the substrate S. As one moves from the edge to the center C, the circumference for the same central angle may reduce on the substrate S. Accordingly, If the rotating substrate S is cleaned using a brush that rotates with the same speed as a whole, the contact time between the substrate S and the brush may increase as one moves from the edge to the central region of the substrate S. Such an increase of contact time may cause damage to the substrate S. On the other hand, to prevent substrate damage, reducing the pressure with which the brush presses against the substrate S may lead to an issue where cleaning is less effectively achieved towards the edge regions of the substrate S. On the other hand, the substrate cleaning apparatus 1 may reduce the rotation speed of the center brush member 210 compared to the rotation speed of the side brush member 220, thereby preventing damage to the substrate S due to an increase in contact time. In addition, the substrate cleaning apparatus 1 may allow cleaning to be performed while the roll brush module 20 exerts sufficient pressure on the substrate S. Accordingly, the substrate cleaning apparatus 1 may achieve effective cleaning even in the edge region of the substrate S.

Furthermore, a center brush member 210 may be provided as described above in FIG. 3. In addition, since the side speed control member 205b described above in FIG. 4 is omitted, the side brush member 220 may be provided to be rotated together with the drive shaft 200. In such case, as the rotation speed of the center brush member 210 is decelerated compared to the rotation speed of the drive shaft 200 while the side brush member 220 rotates at the same rotation speed as the drive shaft 200, the rotation speed of the center brush member 210 may be lower than the rotation speed of the side brush member 220.

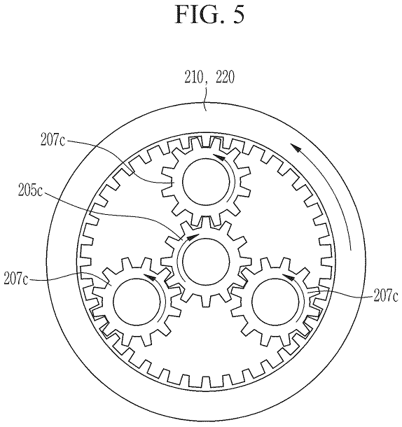

FIG. 5 is a drawing representing an example of a speed control member 205c and an example of a connection member 207c.

Referring to FIG. 5, the speed control member 205c may be disposed around the outside circumference of the drive shaft 200. The inner center region of the speed control member 205c may be connected to the drive shaft 200. The speed control member 205c may be disposed in a space formed inside of the brush member 210 and 220. The speed control member 205c may be coupled to the drive shaft 200 and may be rotated together with the drive shaft 200. The speed control member 205c may be rotated at the same speed as the drive shaft 200. For example, the speed control member 205c may be coupled to the outside circumference of the drive shaft 200. The speed control member 205c may be disposed between the drive shaft 200 and the inner sides of the brush members 210, 220 so that the rotation speed of the brush members 210, 220 with respect to the rotation speed of the drive shaft 200 may be controlled. In other words, the rotation speed of the brush members 210 and 220 may be adjusted to be lower than the rotation speed of the drive shaft 200 by the speed control member 205c. The speed control member 205c may be provided to have a gear structure. In addition, a gear tooth may be disposed along the circumference direction intersecting the length direction of the drive shaft 200 on the inner side of brush members 210 and 220. In addition, a connection member 207c with a gear structure may be disposed between the speed control member 205c and the inner side of the brush members 210, 220. At least three or more connection members 207c may be provided, and each connection member 207c may have a structure corresponding to each other. The plurality of connection members 207c may be disposed to be spaced apart from each other around the circumference of the speed control member 205c. The central angle at which the plurality of connection members 207c is spaced apart from each other may correspond to each other. Accordingly, the rotation of the speed control member 205c may be effectively transmitted to the brush members 210 and 220, and the speed control member 205c may be prevented from deviating from the correct position.

The method of adjusting the rotation speed of the brush members 210, 220 may be similar to or the same as the method described in FIG. 3 to FIG. 4, so repeated explanations are omitted.

The structure described in FIG. 5 may be applied to the center brush member 210, and the structure described in FIG. 4 may be applied to the side brush member 220.

In addition, the structure described in FIG. 5 may be applied to center brush member 210, and side brush member 220 may be rotated with drive shaft 200.

In addition, the structure described in FIG. 5 may be applied to the side brush member 220, and the structure described in FIG. 3 may be applied to the center brush member 210.

In addition, the structure described in FIG. 5 may be applied to the center brush member 210 and the side brush member 220.

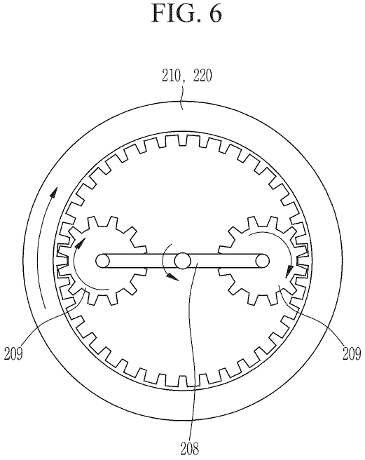

FIG. 6 is a drawing representing an example of a speed control member 209.

Referring to FIG. 6, the speed control member 209 may be disposed in a space formed inside of the brush members 210 and 220. The speed control member 209 may be disposed to be spaced apart from the drive shaft 200 by the predetermined distance. The connection shaft 208 may be coupled to the drive shaft 200. The connection shaft 208 may extend from the drive shaft 200 toward the inner sides of the brush members 210 and 220. The length direction of the connection shaft 208 may be provided to intersect with the length direction of the drive shaft 200. As an example, the length direction of the connection shaft 208 may be orthogonal to the length direction of the drive shaft 200. A plurality of connection shafts 208 may extend from the drive shaft 200.

The speed control member 209 may be connected to the end of the connection shaft 208. The inner central region of the speed control member 209 may be provided to be rotatable with respect to the connection shaft 208. The friction power between the connection shaft 208 and the speed control member 209 may be adjusted. The speed control member 209 may be rotated while being in contact with the inner sides of the brush members 210 and 220. As an example, the speed control member 209 may be provided in a gear structure and may be provided to be meshed with the gear tooth formed on the inner sides of the brush member 210, and 220.

When the drive shaft 200 is rotated, the connection shaft 208 may be rotated together. When the connection shaft 208 is rotated, the speed control member 209 connected to the connection shaft 208 may be rotated with respect to the connection shaft 208 and may move along the inner sides of the brush members 210, 220 by meshing with the inner sides of the brush members 210, 220. In addition, the brush members 210 and 220 may be rotated by a restoring force interacting with the speed control member 209.

The rotation speed of the brush members 210 and 220 may be adjusted through the friction power acting between the connection shaft 208 and the speed control member 209. In other words, in case the ratio of the gear tooth of the brush members 210, 220 and the gear tooth of the speed control member 209 is the same, by increasing the friction power acting between the connection shaft 208 and the speed control member 209, the rotation speed of the brush members 210 and 220 may be increased.

In addition, the rotation speed of brush members 210, 220 may be adjusted by a similar mechanism as described in FIG. 3 and FIG. 4 based on the ratio of gear tooth of the brush members 210, 220 and the gear tooth of the speed control member 209. Thus, when the friction power between the connection shaft 208 and the speed control member 209 is the same, the rotation speed of the brush member 210 and 220 may be reduced by increasing the number of the gear tooth disposed on the inner side of the brush member 210 and 220 compared to the number of gear tooth of the speed control member 209.

The structure described in FIG. 6 may be applied to the center brush member 210, and the structure described in FIG. 4 and FIG. 5 may be applied to the side brush member 220.

In addition, the structure described in FIG. 6 may be applied to the center brush member 210, and the side brush member 220 may be rotated with the drive shaft 200.

In addition, the structure described in FIG. 6 may be applied to the side brush member 220, and the structure described in FIG. 3 and FIG. 5 may be applied to the center brush member 210.

In addition, the structure described in FIG. 6 may be applied to the center brush member 210 and the side brush member 220.

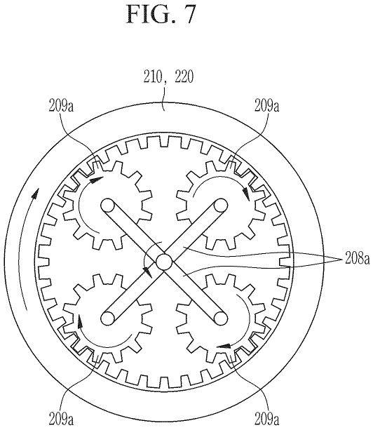

FIG. 7 is a drawing representing an example of a speed control member 209a.

Referring to FIG. 7, the speed control member 209a may be disposed in a space formed inside of the brush members 210 and 220. The speed control member 209a may be disposed to be spaced apart from the drive shaft 200 by the predetermined distance. The connection shaft 208a may be coupled to the drive shaft 200. The connection shaft 208a may extend from the drive shaft 200 toward the inner sides of the brush members 210 and 220. The length direction of the connection shaft 208a may be provided to intersect the length direction of the drive shaft 200. As an example, the length direction of the connection shaft 208a may be orthogonal to the length direction of the drive shaft 200. A plurality of connection shafts 208a may be extended from the drive shaft 200. The central angles at which the plurality of connection shaft 208a are spaced apart from each other may correspond to each other.

The speed control member 209a may be connected to one end of the connection shaft 208a. The inner central region of the speed control member 209a may be provided to be rotatable with respect to the connection shaft 208a. The friction power between the connection shaft 208a and the speed control member 209a may be adjusted. Each friction power between the speed control member 209a and the connection shaft 208a may be equal or different from each other. As an example, the speed control member 209a may be provided in a gear structure and may be provided to be meshed with the gear tooth formed on the inner sides of the brush member 210 and 220.

When the connection shaft 208a is rotated, the speed control member 209a connected to the connection shaft 208 may be rotated with respect to the connection shaft 208a and may move along the inner sides of the brush members 210, 220 by meshing with the inner sides of the brush members 210, 220. In addition, the brush members 210 and 220 may be rotated by restoring force interacting with the speed control member 209a.

The rotation speed of the brush members 210 and 220 may be adjusted through the friction power acting between the connection shaft 208a and the speed control member 209a. In other words, when the gear tooth ratio of the brush members 210, 220 is the same as the gear tooth ratio of the speed control member 209a, an increasing the friction power between the connection shaft 208a and the speed control member 209a may lead to an increase in the rotation speed of the brush members 210, 220. In addition, the rotation speed of brush members 210 and 220 may be more effectively controlled by individually adjusting the friction power acting between each of the plurality of speed control members 209a and the connection shaft 208a.

In addition, the rotation speed of brush members 210, and 220 may be adjusted by a similar mechanism as described in FIG. 3 and FIG. 4 based on the gear tooth ratio of the brush members 210 and 220 and the gear tooth ratio of speed control member 209a. Thus, when the friction power between the connection shaft 208a and the speed control member 209a is the same, if a number of gear tooth disposed on the inner side of the brush members 210 and 220 are increased compared to the number of gear tooth of the speed control member 209a, the rotation speed of the brush members 210 and 220 may be reduced.

The structure described in FIG. 7 may be applied to the center brush member 210, and the structure described in FIG. 4, FIG. 5 and FIG. 6 may be applied to the side brush member 220.

In addition, the structure described in FIG. 7 may be applied to the center brush member 210, and the side brush member 220 may be rotated with the drive shaft 200.

In addition, the structure described in FIG. 7 may be applied to the side brush member 220, and the structure described in FIG. 3, FIG. 5 and FIG. 6 may be applied to the center brush member 210.

In addition, the structure described in FIG. 7 may be applied to the center brush member 210 and the side brush member 220.

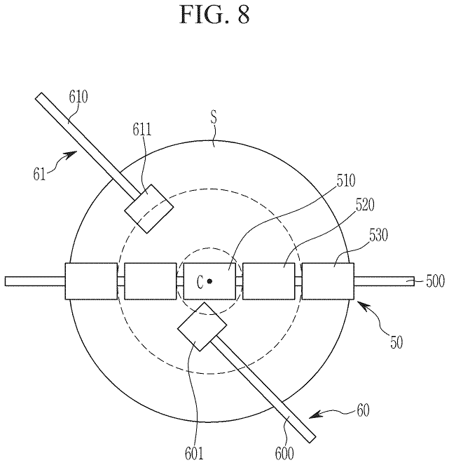

FIG. 8 is a drawing representing an example of a roll brush module 50 and an example of an auxiliary brush module 60 and 61.

Referring to FIG. 8, the roll brush module 50 may rotate while being in contact with an outer surface of the substrate S to remove foreign substances attached to the substrate S. The roll brush module 50 may rotate while being in contact with the first surface of the substrate S to enable cleaning for the first surface of the substrate S. The roll brush module 50 may rotate while being in contact with the second surface of the substrate S to enable cleaning of the second surface of the substrate S.

The roll brush module 50 may include a drive shaft 200 and a plurality of brush members 510, 520 and 530.

The drive shaft 500 has a predetermined length. When viewed along an upward and downward direction, the drive shaft 500 may be positioned to pass through the center C of the substrate S. A length of the drive shaft 500 may be provided to be larger than the diameter of the substrate S, so that each end of the drive shaft 500 having both ends may be positioned outside the edges of the substrate S.

Each of the plurality of brush members 510, 520, and 530 is disposed around the outside circumference of the drive shaft 500. Each of the plurality of brush members 510, 520, and 530 may be rotated according to the rotation of the drive shaft 500. Each of the plurality of brush members 510, 520 and 530 may be provided in a cylinder shape. Protrusions may be disposed for improving cleaning efficiency around the outside circumference of the brush member 510, 520 and 530.

The plurality brush members 510, 520, 530 positioned closer to the center C of the substrate S may be provided with a rotation speed lower than those positioned farther away from the center C of the substrate S. Among the plurality brush members 510, 520, 530, the rotation speed of the one positioned on the central region C of the substrate S may be provided to be lower than the rotation speed of the drive shaft 500.

The brush member 510, 520, 530 may include a center brush member 510, a middle brush member 520, and a side brush member 530.

The center brush member 510 may be disposed around the outside circumference of the drive shaft 500. The center brush member 510 may be provided in a cylinder shape. Protrusions may be disposed for improving cleaning efficiency around the outside circumference of the center brush member 510. When viewed along an upward and downward direction, the center brush member 510 may be positioned to pass through the center C of the substrate S. The center brush member 210 may be positioned in a manner where the lengths extending in both directions correspond to each other with respect to the center C of the substrate S as a reference. That is, both ends of the center brush member 510 may be positioned on a circumference having a predetermined radius with respect to the center C of the substrate S as a reference. In this case, if the circle of the predetermined radius intersects a point of both ends of the center brush member 510, respectively, it may be understood that both ends of the center brush member 210 may be positioned along the circumference. In addition, if both ends of the center brush member 510 are inscribed to a circle of a predetermined radius, respectively, it may be understood that both ends of the center brush member 510 may be positioned along the circumference.

The middle brush member 520 may be disposed outside circumference of the drive shaft 500. The middle brush member 520 may be provided in a cylinder shape. In a vertical direction to the drive shaft 500, the size of the outside circumference of the middle brush member 520 may correspond to the size of the outside circumference of the center brush member 510. Protrusions may be disposed for improving cleaning efficiency around the outside circumference of the middle brush member 520. The middle brush member 220 may be disposed on each side of the center brush member 510 having both sides. The inner end of the middle brush member 520 faces the center C of the substrate S, and the outer end of the middle brush member 520 faces the opposite side of the center C of the substrate S. The middle brush member 520 may be provided with a rotation speed faster than the center brush member 510.

An inner end of the middle brush member 520 may be disposed to be spaced apart from one end of the center brush member 510. That is, the middle brush member 520 may be positioned on the outside of a circle having a predetermined radius with respect to the center C of the substrate S as a reference. In this case, one point of the inner end of the middle brush member 520 may be circumscribed to the circle of the predetermined radius. In addition, the inner end of the middle brush member 520 may be positioned to be spaced apart from the circle having a predetermined radius.

The middle brush member 520 disposed on each side of the center brush member 510 having both sides may have corresponding lengths to each other along the length direction of the drive shaft 500.

The side brush member 530 may be disposed around the outside circumference of the drive shaft 500. The side brush member 530 may be provided in a cylinder shape. In a vertical direction to the drive shaft 500, the size of the outside circumference of the side brush member 530 may correspond to the size of the outside circumference of the center brush member 510. Protrusions may be disposed for improving cleaning efficiency around the outside circumference of the side brush member 530. The side brush member 530 may be disposed on one side of the middle brush member 520, respectively. The side brush member 530 may be disposed in the opposite direction of the center brush member 510 with respect to the middle brush member 520 as a reference. The inner end of the side brush member 530 faces the center C of the substrate S, and the outer end of the side brush member 530 faces the opposite side of the center C of the substrate S. The side brush member 530 may be provided with a rotation speed faster than the center brush member 510. The side brush member 530 may be provided with a rotation speed faster than the middle brush member 520.

An inner end of the side brush member 530 may be disposed to be spaced apart from one end of the middle brush member 520. An outer end of the side brush member 530 may be positioned on an outside of an edge of the substrate S. When viewed in an upward and downward direction, the side brush member 530 may be positioned on a region between a predetermined distance separated point from the center C of the substrate S and an edge of the substrate S. That is, the side brush member 530 may be positioned on the outside of a circle having a predetermined radius with respect to the center C of the substrate S as a reference. In this case, one point of the inner end of the side brush member 530 may be circumscribed to the circle of the predetermined radius. In addition, the inner end of the side brush member 530 may be positioned to be spaced apart from the circle having a predetermined radius.

The side brush members 530 disposed on each side of the center brush member 510 having both sides may have a corresponding length along the length direction of the drive shaft 200.

The auxiliary brush modules 60, 61 may be positioned in a region different from the roll brush module 50 to complement the cleaning of the substrate S by the roll brush module 50. The auxiliary brush modules 60 and 61 may perform cleaning for the substrate S by being positioned over the gap in the region where one end of the plurality of brush members 510, 520, 530 faces each other on the substrate. The auxiliary brush module 60 and 61 may be positioned on the first surface of the substrate S or the second surface of the substrate S corresponding to the roll brush module 50.

The auxiliary brush module 60 and 61 may include a first auxiliary brush module 60 and a second auxiliary brush module 61.

The first auxiliary brush module 60 may include a first auxiliary drive shaft 600 and a first auxiliary brush member 601.

The first auxiliary drive shaft 600 may have a predetermined length. When viewed along an upward and downward direction, the first auxiliary drive shaft 600 may be positioned to be inclined with respect to the radius direction for the center C of the substrate S. Also, when viewed along an upward and downward direction, the first auxiliary drive shaft 600 may be positioned in a radius direction with respect to the center C of the substrate S. The first auxiliary drive shaft 600 may be positioned to be spaced apart from the roll brush module 50.

The first auxiliary brush member 601 may be disposed around the outside circumference of the first auxiliary drive shaft 600. The first auxiliary brush member 601 may be provided in a cylinder shape. Protrusions may be disposed for improving cleaning efficiency around the outside circumference of the first auxiliary brush member 601. The first auxiliary brush member 601 may be positioned to be spaced apart from the center C of the substrate S in the radius direction. When viewed along an upward and downward direction, the first auxiliary brush member 601 may be positioned on the circumference passing through the gap formed in the region where one end of the center brush member 510 and the inner end of the middle brush member 520 faces each other. That is, a circle passing through one end of the center brush member 510 may pass through the first auxiliary brush member 601. In addition, a circle passing through an inner end of the middle brush member 520 may pass through the first auxiliary brush member 601. As the substrate S rotates, the region positioned in the gap formed between the center brush member 510 and the middle brush member 520 in the substrate S may pass through the first auxiliary brush member 601. Accordingly, the first auxiliary brush member 601 may perform cleaning on a region positioned in a gap formed between one end of the plurality of brush members 510, 520 and 530 in the substrate S.

The second auxiliary brush module 61 may include a second auxiliary drive shaft 610 and a second auxiliary brush member 611.

The second auxiliary drive shaft 610 may have a predetermined length. When viewed along an upward and downward direction, the second auxiliary drive shaft 610 may be positioned to be inclined with respect to the radius direction for respect to the center C of the substrate S. Also, when viewed along an upward and downward direction, the second auxiliary drive shaft 610 may be positioned in a radius direction with respect to the center C of the substrate S. The second auxiliary drive shaft 600 may be positioned to be spaced apart from the roll brush module 50.

The second auxiliary brush member 611 may be positioned around the outside circumference of the second auxiliary drive shaft 610. The second auxiliary brush member 611 may be provided in a cylinder shape. Protrusions may be disposed for improving cleaning efficiency around the outside circumference of the second auxiliary brush member 611. The second auxiliary brush member 611 may be positioned to be spaced apart from the center C of the substrate S in the radius direction. When viewed along an upward and downward direction, the second auxiliary brush member 611 may be positioned on the circumference passing through a gap formed between the outer end of the middle brush member 520 and the inner end of the side brush member 530 facing each other. That is, a circle passing through the outer end of the middle brush member 520 may pass through the second auxiliary brush member 611. In addition, a circle passing through the inner end of the side brush member 530 may pass through the second auxiliary brush member 611. As the substrate S rotates, the region positioned in the gap formed between the middle brush member 520 and the side brush member 530 in the substrate S may pass through the second auxiliary brush member 611. Accordingly, the second auxiliary brush member 611 may perform cleaning on a region positioned in the gap formed between one end of the plurality of brush members 510, 520 and 530 in the substrate S.

The center brush member 510 may have a structure described in FIGS. 3, FIGS. 5 to 7 to adjust the rotation speed.

The middle brush member 520 may have a structure described in FIG. 4 to FIG. 7 to adjust the rotation speed.

The side brush member 530 may have a structure described in FIG. 4 to FIG. 7 to adjust the rotation speed. In addition, the side brush member 530 may be rotated at the same speed as the drive shaft 500.

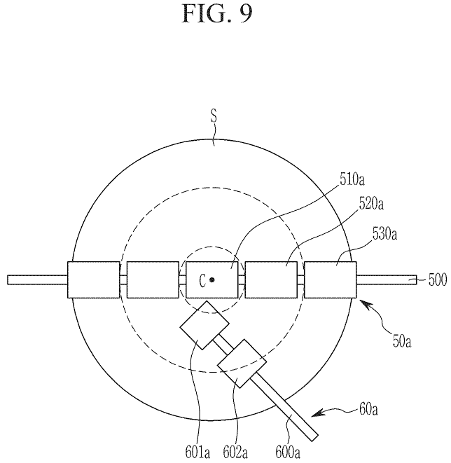

FIG. 9 is a drawing representing an example of a roll brush module 50a and an example of an auxiliary brush module 60a.

Referring to FIG. 9, the roll brush module 50a may rotate while being in contact with an outer surface of the substrate S to remove foreign substances attached to the substrate S. The roll brush module 50a may rotate while being in contact with the first surface of the substrate S to enable cleaning of the first surface of the substrate S. The roll brush module 50a may rotate while being in contact with the second surface of the substrate S to enable cleaning of the second surface of the substrate S.

The roll brush module 50a may include a drive shaft 500 and a plurality of brush members 510a, 520a and 530a. The roll brush module 50a may be identical or similar to the roll brush module 50a of FIG. 8, so repeated descriptions are omitted.

The auxiliary brush modules 60a may be positioned in a different region from the roll brush module 50a to complement the cleaning on the substrate S by the roll brush module 50a. The auxiliary brush modules 60a may perform cleaning of the substrate S by being positioned over the gap in the region where one end of the plurality of brush members 510a, 520a, 530a faces each other on the substrate. The auxiliary brush module 60a may be positioned on the first surface of the substrate S or the second surface of the substrate S corresponding to the roll brush module 50a.

The auxiliary brush module 60a may include an auxiliary drive shaft 600a and auxiliary brush members 601a and 602a.

The auxiliary drive shaft 600a may have a predetermined length. When viewed along an upward and downward direction, the auxiliary drive shaft 600a may be positioned to be inclined with respect to the radius direction for respect to the center C of the substrate S. Also, when viewed along an upward and downward direction, the auxiliary drive shaft 600a may be positioned in a radius direction with respect to the center C of the substrate S. The auxiliary drive shaft 600a may be positioned to be spaced apart from the roll brush module 50a.

The auxiliary brush member 601a and 602a may be disposed around the outside circumference of the auxiliary drive shaft 600a. The auxiliary brush member 601a and 602a may be provided in a cylinder shape. Protrusions may be disposed for improving cleaning efficiency around the outside circumference of the auxiliary brush member 601a and 602a.

The auxiliary brush member 601a and 602a may include a first auxiliary brush member 601a and a second auxiliary brush member 602a.

The first auxiliary brush member 601a may be positioned to be spaced apart from the center C of the substrate S in the radius direction. When viewed along an upward and downward direction, the first auxiliary brush member 601a may be positioned on a circumference passing through a gap formed between one end of the center brush member 510a and the inner end of the middle brush member 520a. That is, a circle passing through one end of the center brush member 510a may pass through the first auxiliary brush member 601a. In addition, a circle passing through an inner end of the middle brush member 520a may pass through the first auxiliary brush member 601a. As the substrate S rotates, the region positioned at the gap formed between the center brush member 510a and the middle brush member 520a in the substrate S may pass through the first auxiliary brush member 601a. Accordingly, the first auxiliary brush member 601a may perform cleaning on a region positioned in a gap formed between one end of the plurality of brush members 510a, 520a and 530a in the substrate S.

The second auxiliary brush member 602a may be positioned to be spaced apart from the center C of the substrate S in the radius direction. The second auxiliary brush member 602a may be positioned farther from the center C of the substrate S than the first auxiliary brush member 601a. When viewed along an upward and downward direction, the second auxiliary brush member 602a may be positioned on a circumference passing through a gap formed between the outer end of the middle brush member 520a and the inner end of the side brush member 530a. That is, a circle passing through the outer end of the middle brush member 520a may pass through the second auxiliary brush member 602a. In addition, a circle passing through the inner end of the side brush member 530a may pass through the second auxiliary brush member 602a. As the substrate S rotates, the region positioned in the gap formed between the middle brush member 520a and the side brush member 530a in the substrate S may pass through the second auxiliary brush member 602a. Accordingly, the second auxiliary brush member 602a may perform cleaning on a region positioned in a gap formed between one end of the plurality of brush members 510a, 520a and 530a in the substrate S.

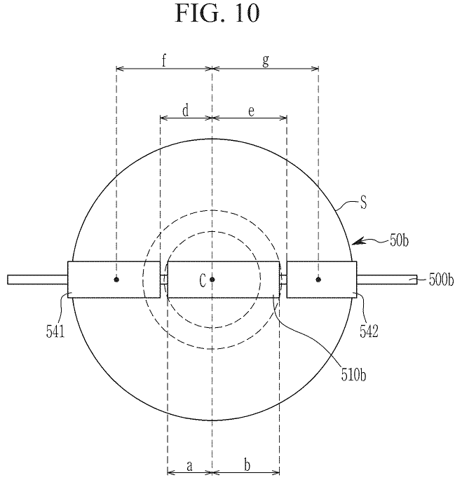

FIG. 10 is a drawing representing an example of a roll brush module 50b.

Referring to FIG. 10, the roll brush module 50b may rotate while being in contact with an outer surface of the substrate S to remove foreign substances attached to the substrate S. The roll brush module 50b may rotate while being in contact with the first surface of the substrate S to enable cleaning of the first surface of the substrate S. The roll brush module 50b may rotate while being in contact with the second surface of the substrate S to enable cleaning on the second surface of the substrate S.

The roll brush module 50b may include a drive shaft 500b and a plurality of brush members 510b, 541 and 542.

The drive shaft 500b has a predetermined length. When viewed along an upward and downward direction, the drive shaft 500b may be positioned to pass through the center C of the substrate S. A length of the drive shaft 500b may be provided to be larger than the diameter of the substrate S, and each end of the drive shaft 500b having both ends may be positioned on an outside of the edge of the substrate S.

Each of the plurality of brush members 510b, 541, and 542 may be disposed around the outside circumference of the drive shaft 500b. Each of the plurality of brush members 510b, 541 and 542 may be rotated according to the rotation of the drive shaft 500b. Each of the plurality of brush members 510b, 541 and 542 may be provided in a cylinder shape. Protrusions may be disposed for improving cleaning efficiency around the outside circumference of the brush member 510b, 541 and 542.

The plurality brush members 510b, 541 and 542 positioned closer to the center C of the substrate S may be provided with a rotation speed lower than those positioned farther away from the center C of the substrate S. The rotation speed of the plurality brush members 510b, 541 and 542 positioned within the central region C of the substrate S may be provided to be lower than the rotation speed of the drive shaft 500b.

The brush members 510b, 541, and 542 may include a center brush member 510b and side brush members 541 and 542.

The center brush member 510b may be disposed around the outside circumference of the drive shaft 500b. The center brush member 510b may be provided in a cylinder shape. Protrusions may be disposed for improving cleaning efficiency around the outside circumference of the center brush member 510b. When viewed along an upward and downward direction, the center brush member 510b may be positioned to pass through the center C of the substrate S. The center brush member 510b may be provided to have different lengths extending in opposite directions with respect to the center C of the substrate S as a reference. In other words, the distance (a) from the center C of the substrate S to one end of the center brush member 510b may be provided to be shorter than the distance (b) from the center C of the substrate S to the other end of the center brush member 510b. Accordingly, the circle passing through one end of the center brush member 510b may pass between the other end of the center brush member 510b and the center C of the substrate S.

The side brush members 541 and 542 may be disposed around the outside circumference of the drive shaft 500b. The side brush members 541 and 542 may be provided in a cylinder shape. In a vertical direction to the drive shaft 500b, the size of the outside circumference of the side brush members 541 and 542 may correspond to the size of the outside circumference of the center brush member 510b. Protrusions may be disposed for improving cleaning efficiency around the outside circumference of the side brush members 541 and 542. The side brush member 541 and 542 may be disposed on each side of the center brush member 510b having both sides. The inner end of the side brush member 541 and 542 faces the center C of the substrate S, and the outer ends of the side brush members 541 and 542 face the opposite side of the center C of the substrate S. The rotation speed of the side brush members 541 and 542 may be provided to be faster than the rotation speed of the center brush member 510b.

The side brush members 541 and 542 may include a first side brush member 541 and a second side brush member 542.

The first side brush member 541 may be disposed on the outer region of one end of the center brush member 510b. An inner end of the first side brush member 541 may be positioned to be spaced apart from one end of the center brush member 510b. An outer end of the first side brush member 541 may be positioned on an outside of the edge of the substrate S. When viewed in an upward and downward direction, the first side brush member 541 may be positioned on a region of between a predetermined distance separated point (d) from the center C of the substrate S and an edge of the substrate S. That is, the first side brush member 541 may be positioned on the outside of a circle having a predetermined radius with respect to the center C of the substrate S as a reference. In this case, one point of the inner end of the first side brush member 541 may be circumscribed to the circle of the predetermined radius. In addition, the inner end of the first side brush member 541 may be positioned to be spaced apart from the circle having a predetermined radius.

The second side brush member 542 may be positioned on the outer region of the other end of the center brush member 510b. An inner end of the second side brush member 542 may be positioned to be spaced apart from other end of the center brush member 510b. An outer end of the second side brush member 542 may be positioned on an outside of the edge of the substrate S. When viewed in an upward and downward direction, the first side brush member 542 may be positioned on a region of between a predetermined distance separated point (e) from the center C of the substrate S and an edge of the substrate S. That is, the second side brush member 542 may be positioned on the outside of a circle having a predetermined radius with respect to the center C of the substrate S as a reference. In this case, one point of the inner end of the second side brush member 542 may be circumscribed to the circle of the predetermined radius. In addition, the inner end of the second side brush member 542 may be positioned to be spaced apart from the circle having a predetermined radius.

The distance (e) from the center C of the substrate S to the inner end of the second side brush member 542 may be provided to be longer than the distance (d) from the center C of the substrate S to the inner end of the first side brush member 541. Accordingly, the circle passing between the other end of the center brush member 510b and the inner end of the second side brush member 542 may pass through the first side brush member 541.

The first side brush member 541 and the second side brush member 542 may be provided with different rotation speeds. The inner end of the first side brush member 541 may be positioned to be closer to the center C of the substrate S than the inner end of the second side brush member 542. Accordingly, the rotation speed of the first side brush member 541 may be provided to be lower than the rotation speed of the second side brush member 542. The rotation speed of the first side brush member 541 may correspond to the distance (f) from the center C of the substrate S to the length direction center of the first side brush member 541, and the rotation speed of the second side brush member 542 may correspond to the distance (g) from the center C of the substrate S to the length direction center of the second side brush member 542.

The center brush member 510b may have a structure described in FIGS. 3, FIG. 5 to FIG. 7 to adjust the rotation speed.

The side brush members 541 and 542 may have a structure described in FIG. 4 to FIG. 7 to adjust the rotation speed.

In addition, the side brush members 541 and 542 may be rotated at the same speed as the drive shaft 500b.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations have been described in detail above, the scope of the present disclosure is not limited to the described implementations, various modifications and improvements of a person of an ordinary skill in the art using the basic concept of the present disclosure defined in the following claim range also belong to the scope of the present disclosure.

What is claimed is:

1. A substrate cleaning apparatus comprising:
a roll brush configured to clean a surface of a substrate, wherein the roll brush includes:
a drive shaft having a predetermined length; and
a plurality of brush members disposed around an outside circumference of the drive shaft, and
wherein a brush member of the plurality of brush members has a lower rotation speed than rotation speeds of other brush members of the plurality of brush members.

2. The substrate cleaning apparatus of claim 1, wherein the plurality of brush members comprises:
a center brush member positioned to pass through a center of the substrate; and
a side brush member disposed on a side of the center brush member, and
wherein the center brush member has a rotation speed lower than a rotation speed of the side brush member.

3. The substrate cleaning apparatus of claim 2, wherein the rotation speed of the center brush member is lower than a rotation speed of the drive shaft.

4. The substrate cleaning apparatus of claim 2, wherein the center brush member defines a space, and wherein the roll brush comprises:
a speed control member inside the space of the center brush member, wherein an inner center region of the speed control member is connected with the drive shaft; and
a connection member between the speed control member and an inner side of the center brush member.

5. The substrate cleaning apparatus of claim 4, wherein the speed control member and the connection member are in a gear structure, and a gear tooth is on the inner side of the center brush member.

6. The substrate cleaning apparatus of claim 2, wherein the center brush member defines a space, and wherein the roll brush comprises:
a speed control member inside the space of the center brush member, the speed control member being rotatable while being in contact with an inner side of the center brush member; and
a connection shaft extending from the drive shaft to the inner side of the center brush member, wherein an end portion of the connection shaft is rotatably connected to the center brush member.

7. The substrate cleaning apparatus of claim 6, wherein:
the speed control member includes a gear structure, and
a gear tooth is on the inner side of the center brush member.

8. The substrate cleaning apparatus of claim 2, wherein the side brush member defines a space, and wherein the roll brush comprises:
a speed control member inside the space of the side brush member, wherein an inner center region of the speed control member is connected with the drive shaft; and
a connection member between the speed control member and an inner side of the side brush member.

9. The substrate cleaning apparatus of claim 8, wherein the speed control member and the connection member are in a gear structure, and a gear tooth is on the inner side of the side brush member.

10. The substrate cleaning apparatus of claim 2, wherein the side brush member defines a space, and where the roll brush comprises:
a speed control member inside the space of the side brush member, the speed control member being rotatable while being in contact with an inner side of the side brush member; and
a connection shaft extending from the drive shaft to the inner side of the side brush member, wherein an end portion of the connection shaft is rotatably connected to the side brush member.

11. The substrate cleaning apparatus of claim 10, wherein:
the speed control member includes a gear structure, and
a gear tooth is on an inner side of the center brush member.

12. The substrate cleaning apparatus of claim 1, comprising:
an auxiliary brush positioned on a region of the substrate cleaning apparatus different from a region in which the roll brush is positioned, the auxiliary brush being configured to clean the surface of the substrate.

13. The substrate cleaning apparatus of claim 12, wherein the auxiliary brush comprises:
an auxiliary drive shaft; and
an auxiliary brush member disposed around an outside circumference of the auxiliary drive shaft and positioned on a circumference passing through a gap, the gap being defined in a region in which ends of the plurality of brush members face each other.

14. The substrate cleaning apparatus of claim 1, wherein the plurality of brush members comprises:
a center brush member extending through a center of the substrate; and
a side brush member disposed on a side of the center brush member, and
wherein a distance between a first end of the center brush member and the center of the substrate is different from a distance between a second end of the center brush member and the center of the substrate.

15. The substrate cleaning apparatus of claim 14, wherein:
a first side brush member disposed outside of the first end of the center brush member; and
a second side brush member disposed outside of the second end of the center brush member, wherein a distance from the center of the substrate to an inner end of the second side brush member is longer than a distance from the center of the substrate to an inner end of the first side brush member.

16. The substrate cleaning apparatus of claim 15, wherein:
a rotation speed of the first side brush member is less than a rotation speed of the second side brush member.

17. A substrate cleaning apparatus comprising:
a substrate support member rotatably supporting a substrate; and
a roll brush configured to clean a surface of the substrate,
wherein the roll brush includes:
a drive shaft;
a center brush member extending through a center of the substrate; and
a side brush member disposed on a side of the center brush member, and
wherein the center brush member has a rotation speed lower than a rotation speed of the side brush member.

18. The substrate cleaning apparatus of claim 17, wherein the center brush member defines a space that receives a gear tooth, and wherein the roll brush includes:
a center speed control member inside the space of the center brush member, wherein an inner center region of the center speed control member is connected with the drive shaft; and
a center connection member having a gear structure and disposed between the center speed control member and an inner side of the center brush member.

19. The substrate cleaning apparatus of claim 18, wherein the side brush member defines a space that receives a gear tooth, and wherein the roll brush comprises:
a side speed control member inside the space of the side brush member, wherein an inner center region of the side speed control member is connected with the drive shaft; and
a side connection member having a gear structure and disposed between the side speed control member and an inner side of the side brush member.

20. A substrate cleaning apparatus comprising:
a substrate support member rotatably supporting a substrate; and
a roll brush configured to clean a surface of the substrate,
wherein the roll brush comprises:
a drive shaft;
a center brush member extending through a center of the substrate; and
a side brush member disposed on a side of the center brush member,
wherein the center brush member and the side brush member are rotatable with respect to the drive shaft, and
wherein the center brush member has a rotation speed lower than a rotation speed of the side brush member.
